(19) United States
(12) Patent Application Publication
(10) Pub. No.: US 2026/0147483 A1
(43) Pub. Date: May 28, 2026

(54) Managing Program Operations in Memory Devices

(71) Applicant: Yangtze Memory Technologies Co., Ltd., Wuhan (CN)

(72) Inventors: Xiangnan ZHAO, Wuhan (CN); Pengyu XU, Wuhan (CN); Hongtao LIU, Wuhan (CN)

(21) Appl. No.: 19/020,022

(22) Filed: Jan. 14, 2025

(30) Foreign Application Priority Data
Nov. 28, 2024 (CN) 202411735097.0

(51) Int. Cl. G06F 3/06

(52) U.S. Cl. CPC G06F 3/0619; G06F 3/0653; G06F 3/0679

(57) ABSTRACT

Example memory devices, systems, and methods for improve retention of the memory cell during a verify operation of the memory device. One example method includes a method of operating a memory device. The method includes programming memory cells coupled to a first word line, and verifying whether the memory cells are programmed to a programming level of a plurality of programming levels, including: applying a verify voltage to the first word line; and applying a first pass voltage to one or more second word lines adjacent to the first word line. The value of the first pass voltage is lower than a value of a second pass voltage applied to the one or more second word lines when performing a read operation on the memory cells coupled to the first word line.

### CROSS-REFERENCE TO RELATED APPLICATIONS

This application claims priority to Chinese Patent Application No. 202411735097.0, filed on Nov. 28, 2024, which is hereby incorporated by reference in its entirety.

### TECHNICAL FIELD

The present disclosure relates to memory devices, systems, and methods for erase operations in memory devices.

### BACKGROUND

Flash memory is a low-cost, high-density, nonvolatile solid-state storage medium that can be electrically erased and reprogrammed. Flash memory includes NOR flash memory and NAND flash memory. Various operations can be performed by a flash memory, for example, program and verify operations, to change the threshold voltage of each memory cell to a respective level. For NAND flash memory, a verify operation is performed at the target word line after the program operation.

### SUMMARY

The present disclosure relates to memory devices, systems, and methods for erase operations in memory devices.

One aspect of the present disclosure features a method of operating a memory device. The method includes programming memory cells coupled to a first word line. The method also includes verifying whether the memory cells are programmed to a programming level of a plurality of programming levels, which includes applying a verify voltage to the first word line; and applying a first pass voltage to one or more second word lines adjacent to the first word line, where a value of the first pass voltage is lower than a value of a second pass voltage applied to the one or more second word lines when performing a read operation on the memory cells coupled to the first word line.

In some implementations, a programming level of the memory cells for verifying whether the memory cells are programmed to the programming level is equal to a programming level of the memory cells during the read operation of the memory cells.

In some implementations, verifying whether the memory cells are programmed to a programming level of a plurality of programming levels further includes applying a third pass voltage to remaining word lines of the memory device other than the first word line and the one or more second word lines, where a value of the third pass voltage is equal to a value of a fourth pass voltage applied to the remaining word lines when performing the read operation on the memory cells.

In some implementations, the first pass voltage is determined based on the verify voltage of the first word line, a value of the first pass voltage decreases when a value of the verify voltage increases.

In some implementations, the plurality of programming levels are sorted into a plurality of groups arranged in an ascending order, where a same value of the first pass voltage is applied when verifying programming levels in a same group, a lower value of the first pass voltage is applied when verifying programming levels in a group with higher order.

In some implementations, the method further includes determining an operating temperature of the memory device; and adjusting the value of the first pass voltage corresponding to the operating temperature.

In some implementations, the value of the first pass voltage decreases when the operating temperature increases.

In some implementations, the operating temperatures are sorted into a plurality of groups arranged in an ascending order, where a same value of the first pass voltage is applied when values of the operating temperatures are in a same group, a lower value of the first pass voltage is applied when values of the operating temperatures are in a group with higher order when verifying whether the memory cells are programmed to a same programming level of the plurality of programming levels.

In some implementations, the value of the first pass voltage is further determined based on a quantity of program cycles of the memory cells, where the value of the first pass voltage increases when the quantity of program cycles increases.

In some implementations, a minimum value of the first pass voltage is greater than 5V.

Another aspect of the present disclosure features a memory device. The memory device includes a memory cell array; and a peripheral circuit coupled to the memory cell array and configured to perform a programming operation on the memory cell array. The programming operation includes programming memory cells of the memory cell array coupled to a first word line; verifying whether the memory cells are programmed to a programming level of a plurality of programming levels, including applying a verify voltage to the first word line; and applying a first pass voltage to one or more second word lines adjacent to the first word line, where a value of the first pass voltage is lower than a value of a second pass voltage applied to the one or more second word lines when performing a read operation on the memory cells coupled to the first word line.

In some implementations, a programming level of the memory cells for verifying whether the memory cells are programmed to the programming level is equal to a programming level of the memory cells during the read operation of the memory cells.

In some implementations, verifying whether the memory cells are programmed to a programming level of a plurality of programming levels further includes applying a third pass voltage to remaining word lines of the memory device other than the first word line and the one or more second word lines, where a value of the third pass voltage is equal to a value of a fourth pass voltage applied to the remaining word lines when performing the read operation on the memory cells.

In some implementations, the first pass voltage is determined based on the verify voltage of the first word line, where a value of the first pass voltage decreases when a value of the verify voltage increases.

In some implementations, the plurality of programming levels are sorted into a plurality of groups arranged in an ascending order, where a same value of the first pass voltage is applied when verifying programming levels in a same group, a lower value of the first pass voltage is applied when verifying programming levels in a group with higher order.

In some implementations, the memory device is further configured to determine an operating temperature of the memory device; and adjust the value of the first pass voltage corresponding to the operating temperature.

In some implementations, the value of the first pass voltage decreases when the operating temperature increases.

In some implementations, the operating temperatures are sorted into a plurality of groups arranged in an ascending order, where a same value of the first pass voltage is applied when values of the operating temperatures are in a same group, a lower value of the first pass voltage is applied when values of the operating temperatures are in a group with higher order when verifying whether the memory cells are programmed to a same programming level of a plurality of programming levels.

In some implementations, the value of the first pass voltage is further determined based on a quantity of program cycles of the memory cells, where the value of the first pass voltage increases when the quantity of program cycles increases.

A further aspect of the present disclosure features a memory system. The memory system includes a memory device and a memory controller coupled to the memory device and configured to control the memory device. The memory device includes a memory cell array; and a peripheral circuit coupled to the memory cell array and configured to perform a programming operation on the memory cell array. The programming operation includes programming memory cells coupled to a first word line; verifying whether the memory cells are programmed to a programming level of a plurality of programming levels, including applying a verify voltage to the first word line; and applying a first pass voltage to one or more second word lines adjacent to the first word line, where a value of the first pass voltage is lower than a value of a second pass voltage applied to the one or more second word lines when performing a read operation on the memory cells coupled to the first word line.

The details of these and other aspects and implementations of the present disclosure are set forth in the accompanying drawings and the description below. Other features, objects, and advantages of the disclosure will be apparent from the description and drawings, and from the claims.

### BRIEF DESCRIPTION OF DRAWINGS

FIG. 1 illustrates an example of a schematic circuit diagram of a memory device including peripheral circuits, according to some aspects of the present disclosure.

FIG. 2 illustrates an example of a side view of cross-sections of a memory cell array including NAND memory strings, according to some aspects of the present disclosure.

FIG. 3 illustrates an example of transactions between a host and a device, according to some aspects of the present disclosure.

FIG. 4A illustrates example threshold voltage distributions of memory cells, according to some aspects of the present disclosure.

FIG. 4B illustrates an example of a side view of cross-sections of a memory cell array, according to some aspects of the present disclosure.

FIG. 4C illustrates a 3D schematic of a memory cell array 400c, according to some aspects of the present disclosure.

FIG. 4D illustrates an example of charge retention with different pitch size of the memory cell array, according to some aspects of the present disclosure.

FIG. 4E illustrates examples of charge retention with different programming level of the memory cells, according to some aspects of the present disclosure.

FIG. 4F illustrates examples of charge retention with different pass voltage applied to the adjacent word lines during a verify operation, according to some aspects of the present disclosure.

FIGS. 5A-5B illustrate a diagram showing example effects of operating temperature on the first pass voltage, according to some aspects of the present disclosure.

FIGS. 6A-6B illustrate a diagram showing example effects of operating cycles on the first pass voltage, according to some aspects of the present disclosure.

FIG. 7 illustrates an example of a flow chart of a method for verify whether a memory cell is programmed to a programming level of a plurality of programming levels, according to some aspects of the present disclosure.

FIG. 8 illustrates a block diagram of an example system having a memory device, according to some aspects of the present disclosure.

FIG. 9A illustrates a diagram of a memory card having a memory device, according to some aspects of the present disclosure.

FIG. 9B illustrates a diagram of a solid-state drive (SSD) having a memory device, according to some aspects of the present disclosure.

Like reference numbers and designations in the various drawings indicate like elements.

### DETAILED DESCRIPTION

Due to the demand for cheaper memory devices with higher density, a memory device (e.g., a 3D NAND flash memory) can be formed with a large number of layers and a high aspect ratio. The large number of layers and the high aspect ratio of such memory devices may present challenges to device retention during a program operation. For example, during the verify operation of the memory device, a pass voltage is applied to the word lines adjacent to the selected word line. The high pass voltage may affect the retention of the memory cells coupled to the selected word line. In other words, the high pass voltage may affect the programming levels of the memory cells coupled to the selected word line during the verify operation.

Implementations of the present disclosure can provide one or more of the following technical effects. For example, the pass voltage applied to the word lines adjacent to the selected word line is based on the programming level of the memory cell coupled to the selected word line. The pass voltage can be further adjusted based on the operating temperature and the number of operating cycles of the memory cells. As such, the change in the pass voltage on the adjacent word lines during the verify process of the memory device can improve the retention of the memory cell in the selected word line by mitigating the charge loss effect during the verify process.

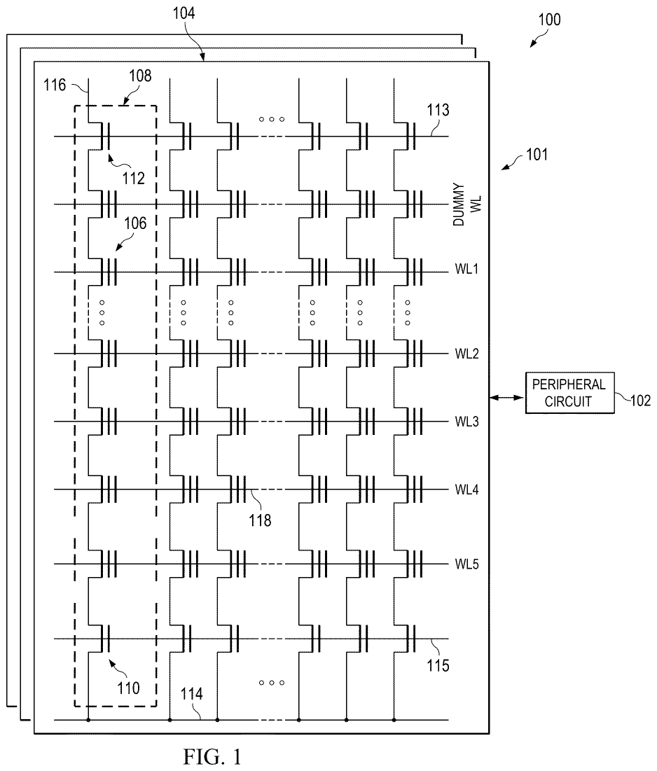

FIG. 1 illustrates an example of a schematic circuit diagram of a memory device 100 including peripheral circuits, according to some aspects of the present disclosure. Memory device 100 can include a memory cell array 101 and peripheral circuits 102 coupled to memory cell array 101. Memory cell array 101 can be a NAND Flash memory cell array in which memory cells 106 are provided in the form of an array of NAND memory strings 108 each extending vertically above a substrate (not shown). In some implementations, each NAND memory string 108 includes a plurality of memory cells 106 coupled in series and stacked vertically. Each memory cell 106 can hold a continuous, analog value, such as an electrical voltage or charge that depends on the number of electrons trapped within a region of memory cell 106. Each memory cell 106 can be either a floating gate type of memory cell including a floating-gate transistor or a charge trap type of memory cell including a charge-trap transistor.

In some implementations, each memory cell 106 is a single-level cell (SLC) that has two possible memory states and thus, can store one bit of data. For example, the first memory state “0” can correspond to a first range of voltages, and the second memory state “1” can correspond to a second range of voltages. In some implementations, each memory cell 106 is a multi-level cell (MLC) that is capable of storing more than a single bit of data in more than four memory states. For example, the MLC can store two bits per cell, three bits per cell (also known as triple-level cell (TLC)), or four bits per cell (also known as a quad-level cell (QLC)). Each MLC can be programmed to assume a range of possible nominal storage values. In one example, if each MLC stores two bits of data, then the MLC can be programmed to assume one of three possible programming levels from an erased state by writing one of three possible nominal storage values to the cell. A fourth nominal storage value can be used for the erased state.

As shown in FIG. 1 each NAND memory string 108 can include a source select gate (SSG) 110 at its source end and a drain select gate (DSG) 112 at its drain end. SSG 110 and DSG 112 can be configured to activate selected NAND memory strings 108 (columns of the array) during read and program operations. In some implementations, the sources of NAND memory strings 108 in the same block 104 are coupled through a same source line (SL) 114, e.g., a common SL. In other words, all NAND memory strings 108 in the same block 104 have an array common source (ACS), according to some implementations. DSG 112 of each NAND memory string 108 is coupled to a respective bit line 116 from which data can be read or written via an output bus (not shown), according to some implementations. In some implementations, each NAND memory string 108 is configured to be selected or deselected by applying a select voltage or a deselect voltage (e.g., 0 V) to respective DSG 112 through one or more DSG lines 113, and/or by applying a select voltage or a deselect voltage (e.g., 0 V) to respective SSG 110 through one or more SSG lines 115.

As shown in FIG. 1, NAND memory strings 108 can be organized into multiple blocks 104, each of which can have a common source line 114, e.g., coupled to the ACS. In some implementations, each block 104 is the basic data unit for erase operations, i.e., all memory cells 106 on the same block 104 are erased at the same time. To erase memory cells 106 in a selected block 104, source lines 114 coupled to selected block 104 as well as unselected blocks 104 in the same plane as selected block 104 can be biased with an erase voltage (Vers), such as a high positive voltage (e.g., 20 V or more). In some examples, erase operation may be performed at a half-block level, a quarter-block level, or a level having any suitable number of blocks or any suitable fractions of a block. Memory cells 106 of adjacent NAND memory strings can be coupled through word lines 118 that select which row of memory cells 106 is affected by read and program operations. Each word line 118 can include a plurality of control gates (gate electrodes) at each memory cell 106 and a gate line coupling the control gates. Example word lines (WLs) shown in FIG. 1 include dummy WL, WL1, WL2, WL3, WL4, and WL5 that are between one or more DSG lines 113 and one or more SSG lines 115.

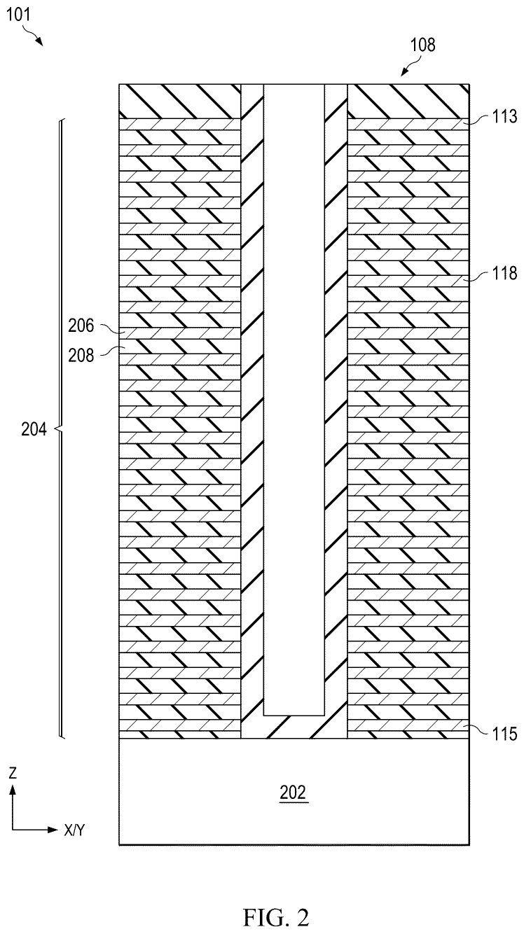

FIG. 2 illustrates an example of a side view of cross-sections of a memory cell array 101 including NAND memory strings 108, according to some aspects of the present disclosure. As shown in FIG. 2, NAND memory string 108 can extend vertically through a memory stack 204 above a substrate 202. Substrate 202 can include silicon (e.g., single crystalline silicon), silicon germanium (SiGe), gallium arsenide (GaAs), germanium (Ge), silicon on insulator (SOI), germanium on insulator (GOI), or any other suitable materials.

Memory stack 204 can include interleaved gate conductive layers 206 and gate-to-gate dielectric layers 208. The number of the pairs of gate conductive layers 206 and gate-to-gate dielectric layers 208 in memory stack 204 can determine the number of memory cells 106 in memory cell array 101. Gate conductive layer 206 can include conductive materials including, but not limited to, tungsten (W), cobalt (Co), copper (Cu), aluminum (Al), polysilicon, doped silicon, silicides, or any combination thereof. In some implementations, each gate conductive layer 206 includes a metal layer, such as a tungsten layer. In some implementations, each gate conductive layer 206 includes a doped polysilicon layer. Each gate conductive layer 206 can include control gates surrounding the memory cells 106, DSG 112, or SSG 110, and can extend laterally as DSG line 113 at the top of memory stack 204, SSG line 115 at the bottom of memory stack 204, or word line 118 between DSG line 113 and SSG line 115.

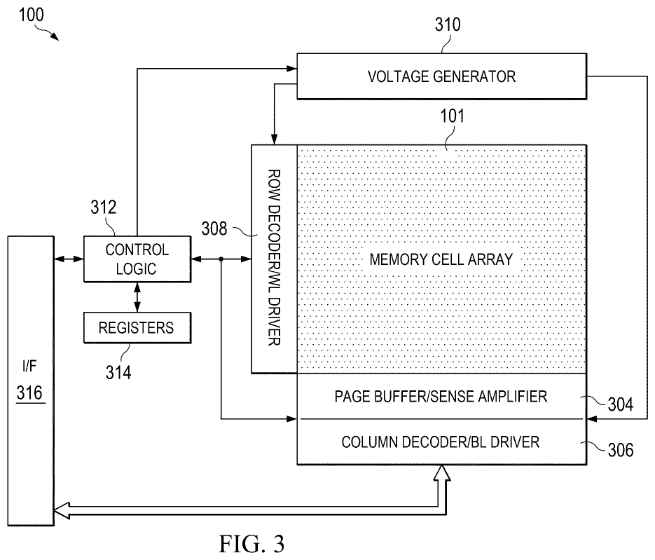

Peripheral circuits 102 can be coupled to memory cell array 101 through bit lines 116, word lines 118, source lines 114, SSG lines 115, and DSG lines 113. Peripheral circuits 102 can include any suitable analog, digital, and mixed-signal circuits for facilitating the operations of memory cell array 101 by applying and sensing voltage signals and/or current signals to and from each target memory cell of the memory cells 106 through bit lines 116, word lines 118, source lines 114, SSG lines 115, and DSG lines 113. Peripheral circuits 102 can include various types of peripheral circuits formed using metal-oxide-semiconductor (MOS) technologies. For example, FIG. 3 illustrates some example peripheral circuits, according to some aspects of the present disclosure. The example peripheral circuits include a page buffer/sense amplifier 304, a column decoder/bit line driver 306, a row decoder/word line driver 308, a voltage generator 310, control logic 312, registers 314, an interface 316, and a data bus. In some examples, additional peripheral circuits not shown in FIG. 3 may be included as well.

Page buffer/sense amplifier 304 can be configured to read and program (write) data from and to memory cell array 101 according to the control signals from control logic 312. In one example, page buffer/sense amplifier 304 may store one page of program data (write data) to be programmed into one page of memory cell array 101. In another example, page buffer/sense amplifier 304 may perform program verify operations to ensure that the data has been properly programmed into memory cells 106 coupled to selected word lines 118. In still another example, page buffer/sense amplifier 304 may also sense the low power signals from bit line 116 that represents a data bit stored in memory cell 106 and amplify the small voltage swing to recognizable logic levels in a read operation. Column decoder/bit line driver 306 can be configured to be controlled by control logic 312 and select one or more NAND memory strings 108 by applying bit line voltages generated from voltage generator 310.

Row decoder/word line driver 308 can be configured to be controlled by control logic 312 and select/deselect blocks 104 of memory cell array 101 and select/deselect word lines 118 of block 104. Row decoder/word line driver 308 can be further configured to drive word lines 118 using word line voltages generated from voltage generator 310. In some implementations, row decoder/word line driver 308 can also select/deselect and drive SSG lines 115 and DSG lines 113 as well. Row decoder/word line driver 308 can be configured to apply a read voltage to selected word line 118 in a read operation on memory cell 106 coupled to selected word line 118.

Voltage generator 310 can be configured to be controlled by control logic 312 and generate the word line voltages (e.g., read voltage, program voltage, pass voltage, local voltage, verification voltage, etc.), bit line voltages, and source line voltages to be supplied to memory cell array 101.

Control logic 312 can be coupled to each peripheral circuit described above and configured to control operations of each peripheral circuit. Registers 314 can be coupled to control logic 312 and include status registers, command registers, and address registers for storing status information, command operation codes (OP codes), and command addresses for controlling the operations of each peripheral circuit. The status registers of registers 314 can include one or more registers configured to store open block information indicative of the open block(s) of all blocks 104 in memory cell array 101, such as having an auto dynamic start voltage (ADSV) list. In some implementations, the open block information is also indicative of the last programmed page of each open block.

Interface 316 can be coupled to control logic 312 and act as a control buffer to buffer and relay control commands received from a host (not shown) to control logic 312 and status information received from control logic 312 to the host. Interface 316 can also be coupled to column decoder/bit line driver 306 via a data bus and act as a data input/output (I/O) interface and a data buffer to buffer and relay the data to and from memory cell array 101.

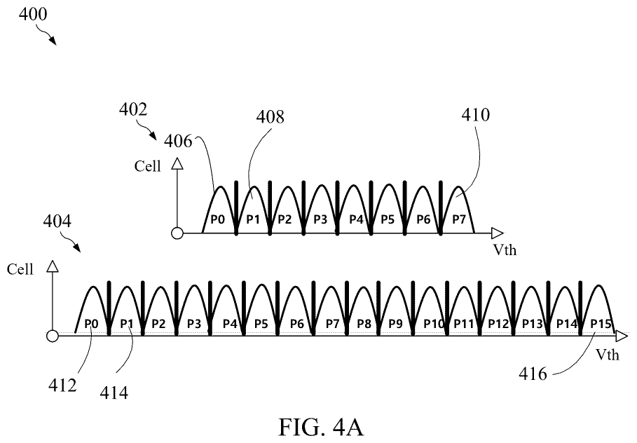

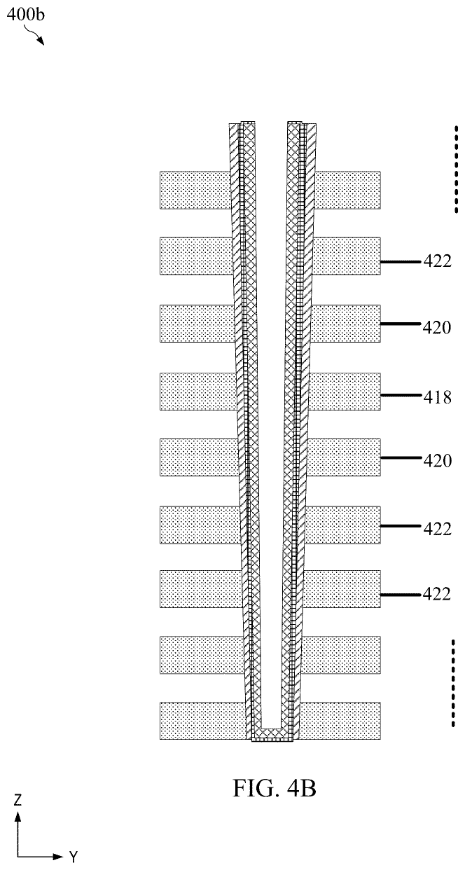

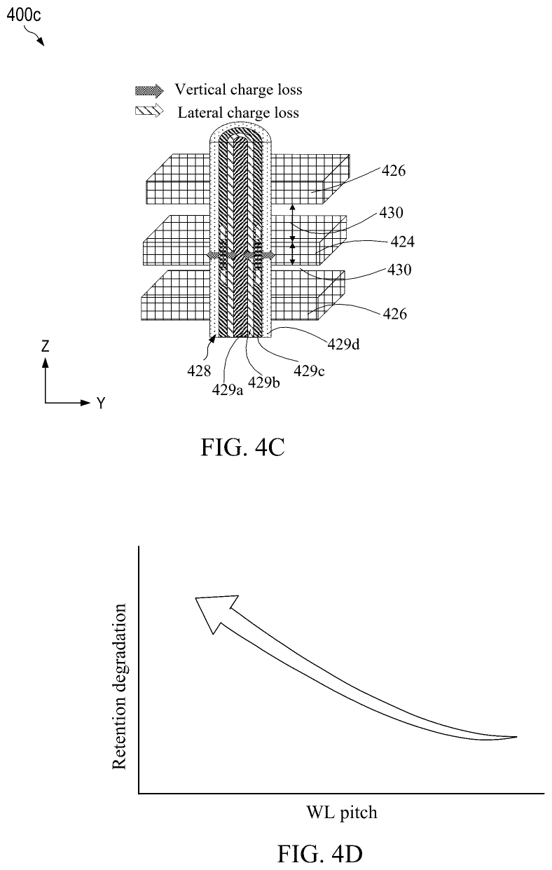

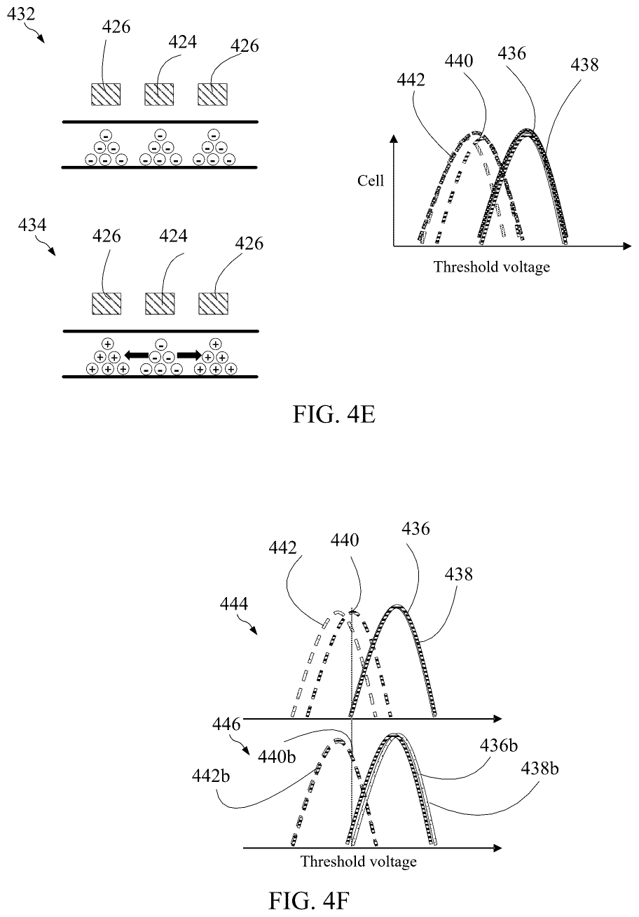

FIG. 4A illustrates example threshold voltage distributions of memory cells, according to some aspects of the present disclosure. In some implementations, the memory cell 106 can be a TLC 402. The TLC 402 can include 8 levels and the memory cell 106 may be programmed into one of the 8 levels, including one level of an erased state and 7 levels of programmed states. Each level may correspond to a respective threshold voltage range of memory cells. For example, the level corresponding to the lowest threshold voltage range of TLC 402 (the left-most threshold voltage distribution in FIG. 4A) may be considered as level 0 406, the level corresponding to the second-lowest threshold voltage range (the second left-most threshold voltage distribution in FIG. 4A) may be considered as level 1 408, and so on until level 7 410 corresponding to the highest threshold voltage range (the right-most threshold voltage distribution in FIG. 4A). In some implementations, the memory cell 106 can be a QLC 404. The QLC 404 can include 16 levels and the memory cell 106 may be programmed into one of the 16 levels, including one level of an erased state and 15 levels of programmed states. Each level may correspond to a respective threshold voltage range of memory cells. For example, the level corresponding to the lowest threshold voltage range of QLC 404 (the left-most threshold voltage distribution in FIG. 4A) may be considered as level 0 412, the level corresponding to the second-lowest threshold voltage range (the second left-most threshold voltage distribution in FIG. 4A) may be considered as level 1 414, and so on until level 15 416 corresponding to the highest threshold voltage range (the right-most threshold voltage distribution in FIG. 4A). In some implementations (not shown in FIG. 4A), the memory cells can be a single-level cell (SLC) with 1 level, a multiple-level cell (MLC) with 4 levels, or a penta-level cell (PLC) with 32 levels.

FIG. 4B illustrates an example of a side view of cross-sections of a memory cell array 400b, according to some aspects of the present disclosure. The memory cell array 400b is similar to, or same as the memory cell array 101 of FIG. 2. The memory cell array can include word lines 418, 420, and 422 coupled to the memory cells 106. In some implementations, the word lines 418, 410, and 422 can be similar to, or same as the gate conductive layers 206 of the memory cell array 101 of FIG. 2. In some implementations, the peripheral circuit 102 coupled to the memory cell array 101 is configured to perform a programming operation of selected memory cells 106 coupled to a first word line 418. The programming operation includes programming the selected memory cells 106 to a programming level and verifying whether the memory cells 106 are programmed to the programming level of a purity of programming levels. In some implementations, verifying whether the memory cells 106 are programmed to a programming level of a plurality of programming levels includes applying a verify voltage to the first word line 418 and applying a first pass voltage to one or more second word lines 420 adjacent to the first word line 418. In some implementations, a value of the first pass voltage is lower than a value of a second pass voltage applied to the one or more second word lines 420. The second pass voltage is applied to the one or more second word lines 420 when performing a read operation on the memory cells 106 coupled to the first word line 418. In some implementations, the programming level of the plurality of programming levels of the memory cells 106 coupled to the first word line 418 for verifying whether the memory cells 106 are programmed to the programming level of the plurality of programming levels is equal to the programming level of the plurality of programming levels of the memory cells 106 coupled to the first word line 418 during the read operation. For example, as shown in FIG. 4A, the memory cell 106 is QLC 404 and programmed to level 15 416. The first pass voltage is applied to the one or more second word lines 420 when verifying whether the memory cell 106 of the first word line 418 programmed to level 15 416. The second pass voltage is applied to one or more second word lines 420 when performing a read operation on the memory cell 106. The read operation is performed to determine whether the memory cell 106 of the first word line 418 is programmed to level 15. The first pass voltage is less than the second pass voltage. In some implementations, as shown in FIG. 4B the first word line 418 is between one or more second word lines 420 along a vertical direction (e.g., the Z direction).

In some implementations, verifying whether the memory cells 106 are programmed to a programming level of a plurality of programming levels includes applying a third pass voltage to one or more remaining word lines 422 of the memory cell array 101. In some implementations, the one or more remaining word lines 422 can be one or more word lines that is not adjacent to the first word line 418. For example, as shown in FIG. 4B, one of the second word line 420 can be in between the first word line 418 and one of the remaining word line 422. As shown in FIG. 4B, the remaining word lines 422 are word lines in the memory cell array 101 other than the first word line 418 and the one or more second word lines 420. In some implementations, a value of the third pass voltage is equal to a value of a fourth pass voltage applied to the remaining word lines 422 when performing the read operation on the memory cells 106 coupled to the first word line 418. In some implementations, the first pass voltage is determined based on the verify voltage of the first word line 418. In some implementations, a value of the first pass voltage decreases when a value of the verify voltage increases. In some other implementations, the plurality of programming levels are sorted into a plurality of groups arranged in an ascending order, where a same value of the first pass voltage is applied when verifying programming levels in a same group, a lower value of the first pass voltage is applied when verifying programming levels in a group with higher order. In some implementations, a value of the first pass voltage is greater than the highest threshold voltage of the corresponding programming level of the memory cells. In some implementations, the first pass voltage is applied to the memory cells coupled to the one or more second word lines 420 to ensure an accurate verify operation of the memory cell coupled to the first word line 418. In some implementations, the first pass voltage decreases as the programming levels of the memory cell coupled to the first word line 418 increases. The decrease of the first pass voltage can reduce the effect of the retention degradation of the memory cell coupled to the first word line 418 as shown in FIG. 4F.

FIG. 4C illustrates a 3D schematic of a memory cell array 400c, according to some aspects of the present disclosure. The memory cell array 400c is similar to, or same as the memory cell array 101 of FIG. 2 or the memory cell array 400b of FIG. 4B. The memory cell array 400c can include word lines 424 and 426 connected to a channel structure 428. In some implementations, the word line 424 is coupled to a memory cell 106 that is selected to be programmed and the word lines 426 are adjacent to the word line 424 in the memory cell array 400c. In some examples, the channel structure 428 can be in the shape of a cylinder or a pillar and can include a core filling layer 429a surrounded by a tunnel layer 429b, a charge trapping layer 429c, and a blocking layer 429d. In some implementations, the core filling layer 429a can include silicon, such as amorphous silicon, polysilicon, or single crystalline silicon, the tunneling layer 429b can include silicon oxide, silicon nitride, or any combination thereof, the blocking layer 429d can include silicon oxide, silicon nitride, high-K dielectrics, or any combination thereof, and the charge trapping layer 429c can include silicon nitride, silicon oxynitride, silicon, or any combination thereof. In some implementations, the tunneling layer 429b, the charge trapping layer 429c, and the blocking layer 429d, collectively referred to as a memory film, can include ONO dielectrics (silicon Oxide-silicon Nitride-silicon Oxide). In some implementations, as shown in FIG. 4C. two adjacent word lines 424 and 426 are separated by a dielectric layer 430. In some implementations, the dielectric layer 430 is filled with a dielectric material. In some implementations, the dielectric layer 430 can be similar to, or same as the gate-to-gate dielectric layer 208 of FIG. 2. In some implementations, the pitch size of the memory cell array 400c is defined by the ratio between a thickness of the word line 424 and a thickness of the dielectric layer 430 along the Z direction. In some implementations, the charge trapping layer 429c stores charges corresponding to a plurality of programming levels of the memory cell 106 similar to the programming levels of FIG. 4A, and the retention of the charges in the charge trapping layer 429c of the memory cells 106 coupled to word lines 424 is corresponding to the pitch size of the memory cell array 400c, as shown in FIG. 4D. In some implementations, as shown in FIG. 4C, the pitch size of the memory cell array 400c refers to the ratio between a thickness of the word line 424 and a thickness of the dielectric layer 430 along the Z direction, where a decrease in the pitch size can results an increase in retention degradation due to the charge tunning through the dielectric layer 430.

FIG. 4D illustrates an example of charge retention with different pitch size of the memory cell array 400c, according to some aspects of the present disclosure. As shown if FIG. 4D, a degradation of charge retention increases as the pitch size of the memory cell array 400c decreases. In some implementations, the degradation of the charge retention can lead to an increase in fail bit count during a read operation of the memory cell 106 coupled to the word line 424.

FIG. 4E illustrates examples of charge retention with different programming levels of the memory cells, according to some aspects of the present disclosure. In some implementations, as shown in FIG. 4E, the charge retention of the memory cells coupled to a selected word line 424 has a strong correlation with the programming levels of the memory cells coupled to adjacent word lines 426.

For example, as shown in FIG. 4E, the memory cells coupled to a selected word line 424 and two adjacent word lines 426 are programmed to a program-program-program (PPP) pattern 432, where the programming level of the memory cells coupled to the adjacent word lines 426 is higher than the programming level of the memory cells coupled to the selected word line 424. For example, if the memory cells coupled to the selected word line 424 is a TLC 402 which can include 8 levels. The memory cells coupled to the selected word line 424 are programmed to a programming level P2 and the memory cells coupled to the adjacent word lines 426 are programmed to a programming level P5, where a value of a threshold voltage corresponding to the programming level P2 of the memory cells coupled to the selected word line 424 is lower than a value of a threshold voltage corresponding to the programming level P5 of the memory cells coupled to the adjacent word lines 426. The threshold voltage of the memory cell coupled to the selected word line 424 decreases from a first threshold voltage 436 to a second threshold voltage 440 after charge retention of the PPP pattern 432.

In some implementations, as shown in FIG. 4E, the memory cells coupled to a selected word line 424 and two adjacent word lines 426 are programmed to an erase-program-erase (EPE) pattern 434, where the programming level of the memory cells coupled to the adjacent word lines 426 is lower than the programming level of the memory cells coupled to the selected word line 424. For example, if the memory cells coupled to the selected word line 424 is a TLC 402 which can include 8 levels. The memory cells coupled to the selected word line 424 are programmed to a programming level P2 and the memory cells coupled to the adjacent word lines 426 are programmed to an erase level P0, where the value of the threshold voltage corresponding to programming level P2 of the memory cells coupled to the selected word line 424 is greater than a value of a threshold voltage corresponding to the erase level P0 of the memory cells coupled to the adjacent word lines 426. After charge retention of the EPE pattern 434, the threshold voltage of the memory cell coupled to the selected word line 424 decreases from a third threshold voltage 438 to a fourth threshold voltage 442. The difference between the third threshold voltage 438 and the fourth threshold voltage 442 is greater than the difference between the first threshold voltage 436 and the second threshold voltage 440.

In some implementations, the greater difference between the third threshold voltage 438 and the fourth threshold voltage 442 of the EPE pattern 434 is caused by a larger shift-down effect of the memory cell coupled to the selected word line 424 when the memory cells of the adjacent word lines 426 are programmed to a lower programming level compared to the programming level of the memory cell coupled to the selected word line 424

FIG. 4F illustrates examples of charge retention with different pass voltages applied to the adjacent word lines during a verify operation, according to some aspects of the present disclosure. In some implementations, a verify operation is performed on a memory cell coupled to the selected word line 424 to verify whether the memory cell is programmed to a selected programming level of a plurality of programming levels after a program operation. The program operation of the memory cell coupled to the selected word line 424 programs the memory cell to the selected programming level of a plurality of programming levels. During the verify operation, a verify pass voltage is applied to the adjacent word lines 426.

For example, in a first case 444, as shown in FIG. 4F, a first verify pass voltage is applied to the adjacent word lines 426, where the first verify voltage is equal to a first read pass voltage applied to the adjacent word lines 426 during a read operation of the memory cells. After charge retention, the first threshold voltage 436 of the first case 444, corresponding to the PPP pattern 432, decreases to the second threshold voltage 440, and the third threshold voltage 438 of the first case 444, corresponding to the EPE pattern 434, decreases to the fourth threshold voltage 442.

In another example, in a second case 446, as shown in FIG. 4F, a second verify pass voltage is applied to the adjacent word lines 426, where the second verify pass voltage is lower than the first read pass voltage applied to the adjacent word lines 426 during a read operation of the memory cell. After charge retention, the first threshold voltage 436b of the second case 446, corresponding to the PPP pattern 432, decreases to the second threshold voltage 440b, and the third threshold voltage 438b of the second case 446, corresponding to the EPE pattern 434, decreases to the fourth threshold voltage 442b. The difference between the third threshold voltage 438b and the fourth threshold voltage 442b of the second case 446 is lower than the difference between the third threshold voltage 438 and the fourth threshold voltage 442 of the first case 444. In some implementations, a lower second verify pass voltage allows a higher third threshold voltage 438b of the EPE pattern 434 of the second case 446 to be programmed during the programming operation of the memory cell coupled to the selected word line 424. In some implementations, in the second case 446, a value of the third threshold voltage 438b of the EPE patter 434 is slightly higher than a value of the first threshold voltage 436b of the PPP pattern 432, which helps to reduce the retention degradation as shown in FIG. 4B.

In some implementations, the smaller difference between the threshold voltages of the two patterns 432 and 434 demonstrates an improvement in charge retention of the memory cell coupled to the selected word line 424 with a verify pass voltage lower than a read pass voltage applied to the adjacent word lines 426 during a verify or read operation. This improvement in charge retention leads to a lower fail bit count during operations of the memory cells.

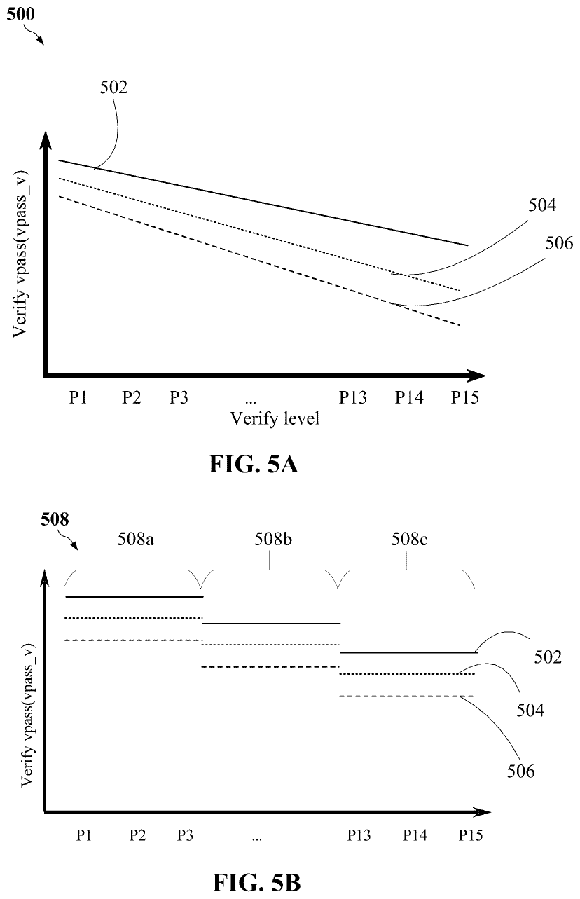

FIGS. 5A-5B illustrate diagrams 500 showing example effects of operating temperature on the first pass voltage, according to some aspects of the present disclosure. In some implementations, the peripheral circuit 102 can include a temperature sensor configured to determine an operating temperature of the memory cell 106 coupled to the first word line 418, and the control logic 312 of the peripheral circuit 102 is configured to adjust the first pass voltage corresponding to the operating temperature. In some implementations, the value of the first pass voltage decreases when the operating temperature increases. In some implementations, the operating temperatures are sorted into a plurality of groups arranged in an ascending order, where a same value of the first pass voltage is applied to the second word lines 420 when values of the operating temperatures are in a same group, a lower value of the first pass voltage is applied to the second word lines 420 when values of the operating temperatures are in a group with higher order when verifying whether the memory cells are programmed to a same programming level of a plurality of programming levels. In some implementations, a range of the operating temperature is −40 C to 100 C. In some implementations, as shown in FIG. 5A, the value of the first pass voltage is further determined based on the verify voltage of the first word line 418 at a same operating temperature, where the value of the first pass voltage decreases when the programming level increases. For example, as shown in FIG. 5A, a temperature of a first operating temperature 502 is lower than a temperature of a second operating temperature 504. The temperature of the second operating temperature 504 is lower than a temperature of a third operating temperature 506. At a same programming level, a value of the first pass voltage applied to the second word lines 420 for the third operating temperature 506 is lower than values of the first pass voltage applied to the second word lines 420 for the second operating temperature 504 and the first operating temperature 502. In some implementations, as shown in FIG. 5B, the plurality of programming levels are sorted into a plurality of groups 508 arranged in an ascending order, where a same first pass voltage is applied to the second word lines 420 when verifying programming levels in a same group 508a, a lower first pass voltage is applied to the second word lines 420 when verifying programming levels in a group 508b with higher order at a same operating temperature. For example, as shown in FIG. 5B, the memory cell 106 coupled to the first word line 418 can be a QLC 404 and the plurality of programming levels of the QLC 404 are shorted into three groups 508a, 508b, 508c in an ascending order. At a same group 508a, 508b, and 508c of the plurality of programming levels, a value of the first pass voltage applied to the second word lines 420 for the third operating temperature 506 is lower than values of the first pass voltage applied to the second word lines 420 for the second operating temperature 504 and the first operating temperature 502.

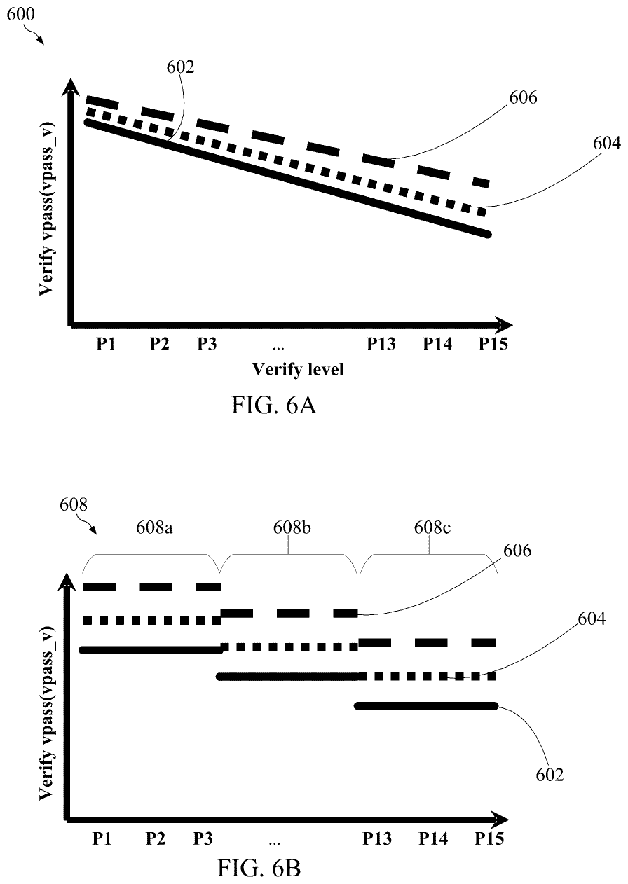

FIGS. 6A-6B illustrate diagrams 600 showing example effects of operating cycles on the first pass voltage, according to some aspects of the present disclosure. In some implementations, the control logic 312 of the peripheral circuit 102 is configured to determine a quality of program cycles of the memory cells 106 coupled to the first word line 418. In some implementations, the value of the first pass voltage is further determined based on the quantity of program cycles of the memory cells 106 coupled to the first word line 418, where the value of the first pass voltage increases when the quantity of program cycles increases. In some implementations, as shown in FIG. 6A, the value of the first pass voltage is further determined based on the verify voltage of the first word line 418 at a same quantity of program cycle, where the value of the first pass voltage decreases when the programming level increases. For example, as shown in FIG. 6A, a quantity of a first programming cycles 602 is lower than a quantity of a second programming cycles 604. The quantity of the programming cycles 604 is lower than a quantity of a third programming cycles 606. At a same programming level, a value of the first pass voltage applied to the second word lines 420 for the third programming cycles 606 is higher than values of the first pass voltage for the second programming cycles 604 and the first programming cycles 602. In some implementations, as shown in FIG. 6B, the plurality of programming levels are sorted into a plurality of groups 608 arranged in an ascending order, where a same first pass voltage is applied to the second word lines 420 when verifying programming levels in a same group 608a, a lower first pass voltage is applied to the second word lines 420 when verifying programming levels in a group 608b with higher order at a same quantity of program cycle. For example, as shown in FIG. 6B, the memory cell 106 coupled to the first word line 418 can be a QLC 404 and the plurality of programming levels of the QLC 404 are shorted into three groups 608a, 608b, 608c in an ascending order. At a same group 608a, 608b, and 608c of the plurality of programming levels, a value of the first pass voltage applied to the second word lines 420 for the third programming cycles 606 is higher than values of the first pass voltage applied to the second word lines 420 for the second programming cycles 604 and the first programming cycles 602.

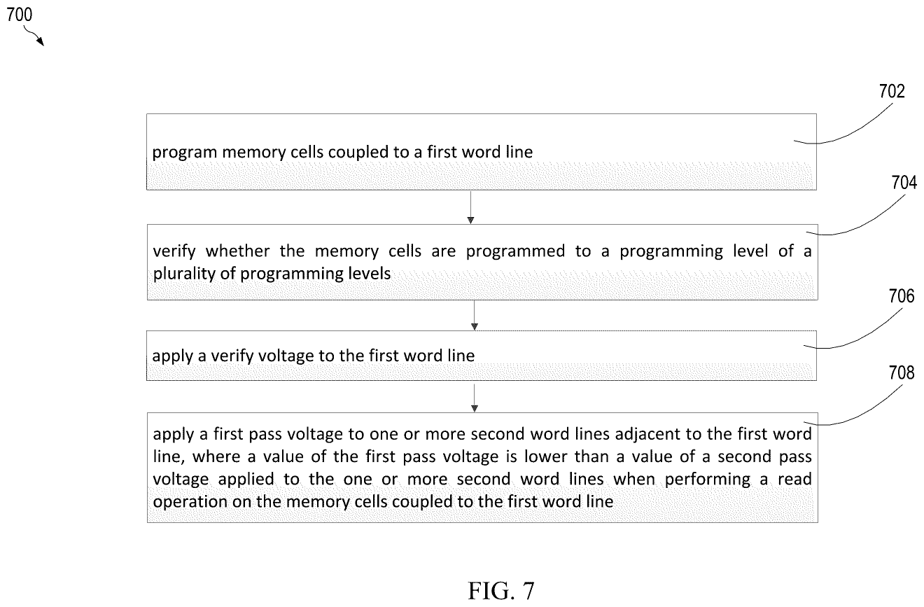

FIG. 7 illustrates an example process 700 of operating a memory device, according to some aspects of the present disclosure.

At operation 702, the memory device programs memory cells (e.g., the memory cells 106 of FIG. 1) coupled to a first word line (e.g., the first word line 418 of FIG. 4B).

At operation 704, the memory device verifies whether the memory cells are programmed to a programming level of a plurality of programming levels, where the operation includes operation 706 and 708.

At operation 706, the memory device applies a verify voltage to the first word line.

At operation 708, the memory device apply a first pass voltage to one or more second word lines (e.g., the second word lines 420 of FIG. 4B) adjacent to the first word line, where a value of the first pass voltage is lower than a value of a second pass voltage applied to the one or more second word lines when performing a read operation on the memory cells coupled to the first word line.

In some implementations, a programming level of the memory cells for verifying whether the memory cells are programmed to the programming level is equal to a programming level of the memory cells during the read operation of the memory cells.

In some implementations, verifying whether the memory cells are programmed to a programming level of a plurality of programming levels further includes: applying a third pass voltage to remaining word lines (e.g., the remaining word lines 422 of FIG. 4B) of the memory device other than the first word line and the one or more second word lines, where a value of the third pass voltage is equal to a value of a fourth pass voltage applied to the remaining word lines when performing the read operation on the memory cells.

In some implementations, the first pass voltage is determined based on the verify voltage of the first word line, where a value of the first pass voltage decreases when a value of the verify voltage increases.

In some implementations, the plurality of programming levels are sorted into a plurality of groups arranged in an ascending order, where a same value of the first pass voltage is applied when verifying programming levels in a same group, a lower value of the first pass voltage is applied when verifying programming levels in a group with higher order.

In some implementations, the operation further includes determining an operating temperature of the memory device; and adjusting the value of the first pass voltage corresponding to the operating temperature.

In some implementations, the value of the first pass voltage decreases when the operating temperature increases.

In some implementations, the operating temperatures are sorted into a plurality of groups arranged in an ascending order, where a same value of the first pass voltage is applied when values of the operating temperatures are in a same group, a lower value of the first pass voltage is applied when values of the operating temperatures are in a group with higher order when verifying whether the memory cells are programmed to a same programming level of the plurality of programming levels.

In some implementations, the value of the first pass voltage is further determined based on a quantity of program cycles of the memory cells, where the value of the first pass voltage increases when the quantity of program cycles increases.

In some implementations, a minimum value of the first pass voltage is greater than 5V.

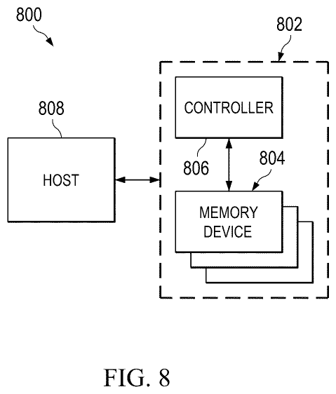

FIG. 8 illustrates a block diagram of an example system 800 having a memory device, according to some aspects of the present disclosure. System 800 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 8, system 800 can include a host 808 and a memory system 802 having one or more memory devices 804 and a memory controller 806. Host 808 can be a processor of an electronic device, such as a central processing unit (CPU), or a system-on-chip (SoC), such as an application processor (AP). Host 808 can be configured to send or receive data to or from memory devices 804.

Memory device 804 can be any memory device disclosed in the present disclosure. Memory controller 806 is coupled to memory device 804 and host 808 and is configured to control memory device 804, according to some implementations. Memory controller 806 can manage the data stored in memory device 804 and communicate with host 808. In some implementations, memory controller 806 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 806 is designed for operating in a high duty-cycle environment SSDs or embedded multi-media-cards (eMMCs) used as data storage for mobile devices, such as smartphones, tablets, laptop computers, etc., and enterprise storage arrays. Memory controller 806 can be configured to control operations of memory device 804, such as read, erase, and program operations. Memory controller 806 can also be configured to manage various functions with respect to the data stored or to be stored in memory device 804 including, but not limited to bad-block management, garbage collection, logical-to-physical address conversion, wear leveling, etc. In some implementations, memory controller 806 is further configured to process error correction codes (ECCs) with respect to the data read from or written to memory device 804. Any other suitable functions may be performed by memory controller 806 as well, for example, formatting memory device 804.

Memory controller 806 can communicate with an external device (e.g., host 808) according to a particular communication protocol. For example, memory controller 806 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

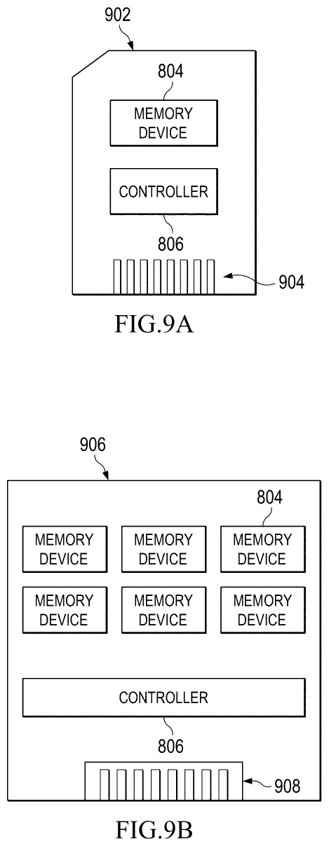

Memory controller 806 and one or more memory devices 804 can be integrated into various types of storage devices, for example, be included in the same package, such as a universal Flash storage (UFS) package or an eMMC package. That is, memory system 802 can be implemented and packaged into different types of end electronic products. In one example shown in FIG. 9A, memory controller 806 and a single memory device 804 may be integrated into a memory card 902. Memory card 902 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 902 can further include a memory card connector 904 coupling memory card 902 with a host (e.g., host 808 in FIG. 8). In another example shown in FIG. 9B, memory controller 806 and multiple memory devices 804 may be integrated into an SSD 906. SSD 906 can further include an SSD connector 908 coupling SSD 906 with a host (e.g., host 808 in FIG. 8). In some implementations, the storage capacity and/or the operation speed of SSD 906 is greater than those of memory card 902.

While this specification contains many specific implementation details, these should not be construed as limitations on the scope of what may be claimed, but rather as descriptions of features that may be specific to particular implementations. Certain features that are described in this specification in the context of separate implementations can also be implemented, in combination, in a single implementation. Conversely, various features that are described in the context of a single implementation can also be implemented in multiple implementations, separately, or in any sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

As used in this disclosure, the terms “a,” “an,” or “the” are used to include one or more than one unless the context clearly dictates otherwise. The term “or” is used to refer to a nonexclusive “or” unless otherwise indicated. The statement “at least one of A and B” has the same meaning as “A, B, or A and B.” In addition, the phraseology or terminology employed in this disclosure, and not otherwise defined, is for the purpose of description only and not of limitation. Any use of section headings is intended to aid reading of the document and is not to be interpreted as limiting; information that is relevant to a section heading may occur within or outside of that particular section.

As used in this disclosure, the term “about” or “approximately” can allow for a degree of variability in a value or range, for example, within 10%, within 5%, or within 1% of a stated value or of a stated limit of a range.

As used in this disclosure, the term “substantially” refers to a majority of, or mostly, as in at least about 50%, 60%, 70%, 80%, 90%, 95%, 96%, 97%, 98%, 99%, 99.5%, 99.9%, 99.99%, or at least about 99.999% or more.

Values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “0.1% to about 5%” or “0.1% to 5%” should be interpreted to include about 0.1% to about 5%, as well as the individual values (for example, 1%, 2%, 3%, and 4%) and the sub-ranges (for example, 0.1% to 0.5%, 1.1% to 2.2%, 3.3% to 4.4%) within the indicated range. The statement “X to Y” has the same meaning as “about X to about Y,” unless indicated otherwise. Likewise, the statement “X, Y, or Z” has the same meaning as “about X, about Y, or about Z,” unless indicated otherwise.

Particular implementations of the subject matter have been described. Other implementations, alterations, and permutations of the described implementations are within the scope of the following claims as will be apparent to those skilled in the art. While operations are depicted in the drawings or claims in a particular order, such operations are not required be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations are not required in all implementations, and the described components and systems can generally be integrated together or packaged into multiple products.

Accordingly, the previously described example implementations do not define or constrain the present disclosure. Other changes, substitutions, and alterations are also possible without departing from the spirit and scope of the present disclosure.

What is claimed is:

1. A method of operating a memory device, comprising:
programming memory cells coupled to a first word line;
verifying whether the memory cells are programmed to a programming level of a plurality of programming levels, comprising:
applying a verify voltage to the first word line; and
applying a first pass voltage to one or more second word lines adjacent to the first word line, wherein a value of the first pass voltage is lower than a value of a second pass voltage applied to the one or more second word lines when performing a read operation on the memory cells coupled to the first word line.

2. The method of claim 1, wherein a programming level of the memory cells for verifying whether the memory cells are programmed to the programming level is equal to a programming level of the memory cells during the read operation of the memory cells.

3. The method of claim 1, wherein verifying whether the memory cells are programmed to a programming level of a plurality of programming levels further comprises:
applying a third pass voltage to remaining word lines of the memory device other than the first word line and the one or more second word lines, wherein a value of the third pass voltage is equal to a value of a fourth pass voltage applied to the remaining word lines when performing the read operation on the memory cells.

4. The method of claim 1, wherein the first pass voltage is determined based on the verify voltage of the first word line, a value of the first pass voltage decreases when a value of the verify voltage increases.

5. The method of claim 1, wherein the plurality of programming levels are sorted into a plurality of groups arranged in an ascending order, wherein a same value of the first pass voltage is applied when verifying programming levels in a same group, a lower value of the first pass voltage is applied when verifying programming levels in a group with higher order.

6. The method of claim 1, further comprising:
determining an operating temperature of the memory device; and
adjusting the value of the first pass voltage corresponding to the operating temperature.

7. The method of claim 6, wherein the value of the first pass voltage decreases when the operating temperature increases.

8. The method of claim 6, wherein the operating temperatures are sorted into a plurality of groups arranged in an ascending order, wherein a same value of the first pass voltage is applied when values of the operating temperatures are in a same group, a lower value of the first pass voltage is applied when values of the operating temperatures are in a group with higher order when verifying whether the memory cells are programmed to a same programming level of the plurality of programming levels.

9. The method of claim 1, wherein the value of the first pass voltage is further determined based on a quantity of program cycles of the memory cells, wherein the value of the first pass voltage increases when the quantity of program cycles increases.

10. The method of claim 1, wherein a minimum value of the first pass voltage is greater than 5V.

11. A memory device comprising:
a memory cell array; and
a peripheral circuit coupled to the memory cell array and configured to perform a programming operation on the memory cell array, the programming operation comprising:
programming memory cells of the memory cell array coupled to a first word line;
verifying whether the memory cells are programmed to a programming level of a plurality of programming levels, comprising:
applying a verify voltage to the first word line; and
applying a first pass voltage to one or more second word lines adjacent to the first word line, wherein a value of the first pass voltage is lower than a value of a second pass voltage applied to the one or more second word lines when performing a read operation on the memory cells coupled to the first word line.

12. The memory device of claim 11, wherein a programming level of the memory cells for verifying whether the memory cells are programmed to the programming level is equal to a programming level of the memory cells during the read operation of the memory cells.

13. The memory device of claim 11, wherein verifying whether the memory cells are programmed to a programming level of a plurality of programming levels further comprises:
applying a third pass voltage to remaining word lines of the memory device other than the first word line and the one or more second word lines, wherein a value of the third pass voltage is equal to a value of a fourth pass voltage applied to the remaining word lines when performing the read operation on the memory cells.

14. The memory device of claim 13, wherein the first pass voltage is determined based on the verify voltage of the first word line, wherein a value of the first pass voltage decreases when a value of the verify voltage increases.

15. The memory device of claim 14, wherein the plurality of programming levels are sorted into a plurality of groups arranged in an ascending order, wherein a same value of the first pass voltage is applied when verifying programming levels in a same group, a lower value of the first pass voltage is applied when verifying programming levels in a group with higher order.

16. The memory device of claim 11, wherein the memory device is further configured to:
determine an operating temperature of the memory device; and
adjust the value of the first pass voltage corresponding to the operating temperature.

17. The memory device of claim 16, wherein the value of the first pass voltage decreases when the operating temperature increases.

18. The memory device of claim 16, wherein the operating temperatures are sorted into a plurality of groups arranged in an ascending order, wherein a same value of the first pass voltage is applied when values of the operating temperatures are in a same group, a lower value of the first pass voltage is applied when values of the operating temperatures are in a group with higher order when verifying whether the memory cells are programmed to a same programming level of a plurality of programming levels.

19. The memory device of claim 11, wherein the value of the first pass voltage is further determined based on a quantity of program cycles of the memory cells, wherein the value of the first pass voltage increases when the quantity of program cycles increases.

20. A memory system, comprising:
a memory device; and
a memory controller coupled to the memory device and configured to control the memory device,
wherein the memory device comprises:
a memory cell array; and
a peripheral circuit coupled to the memory cell array and configured to perform a programming operation on the memory cell array, the programming operation comprising:
programming memory cells coupled to a first word line;
verifying whether the memory cells are programmed to a programming level of a plurality of programming levels, comprising:
applying a verify voltage to the first word line; and
applying a first pass voltage to one or more second word lines adjacent to the first word line, wherein a value of the first pass voltage is lower than a value of a second pass voltage applied to the one or more second word lines when performing a read operation on the memory cells coupled to the first word line.
